(19) United States
(12) Patent Application Publication
(10) Pub. No.: US 2008/0178682 A1
(43) Pub. Date: Jul. 31, 2008

(54) RESONATOR CIRCUIT HAVING REDUCED EFFECTS OF PARASITIC FEED-THROUGH CAPACITANCE

(75) Inventor: Kenneth E. Wojciechowski, Albuquerque, NM (US)

Correspondence Address: BEYER WEAVER LLP, P.O. BOX 70250, OAKLAND, CA, 94612-0250, US

(73) Assignee: THE REGENTS OF THE UNIVERSITY OF CALIFORNIA, Oakland, CA (US)

(21) Appl. No.: 11/306,729

(22) Filed: Jan. 9, 2006

Related U.S. Application Data
(60) Provisional application No. 60/643,063, filed on Jan. 10, 2005.

(51) Int. Cl. G01B 7/16; H03B 5/30

(52) U.S. Cl. 73/778; 331/116 R

(57) ABSTRACT

Parasitic feed-through capacitance effects in a resonator circuit are reduced by separating the resonator signal from the feed-through capacitance signal and then detecting the resonator signal with comparator circuitry. In specific embodiments, the separation of the resonator signal from the feed-through capacitance signal is effected by serial integrator and differentiator circuitry or by trans-impedance amplifier circuitry. The comparator circuitry can include control/delay circuitry for enabling the comparator at a correct time when feed-through capacitance signal has dissipated. The invention can be implemented using microelectromechanical sensors (MEMS) in a strain gauge function.

### CROSS REFERENCE TO RELATED APPLICATIONS

This application claims priority to U.S. Provisional Patent Application No. 60/643,063, filed on Jan. 10, 2005, which is incorporated herein by reference for all purposes.

### FEDERAL RESEARCH STATEMENT

The U.S. government has rights in the disclosed invention pursuant to grants to The University of California. DAAD 19-02-1-0198 Army Research Office

### BACKGROUND OF INVENTION

This invention relates generally to electronic resonator circuits in which a resonating device is used in an oscillator circuit, and more particularly the invention is directed to reducing deleterious effects of feed-through capacitance of the resonator.

Westra et al., “Resonance-mode Selection and Crosstalk Elimination Using Resonator-Synchronized Relaxation Oscillators”, ESSCIRC, 1998 discusses the problems of using resonators in oscillator circuitry, particularly the presence of multiple resonance modes in the resonators and large capacitive crosstalk due to resonator feed-through capacitance. A proposed solution is the use of resonator-synchronized relaxation oscillators in which the selectivity of the oscillator is used as a course selection mechanism for the desired mode, which crosstalk is overcome by exploiting the time-discreet character of the oscillator with a square wave drive. This can be modeled as a parallel combination of the intrinsic resonator and a high-pass filter. The high-pass filter causes quick delay of the output due to the bypass capacitance.

The present invention is directed to circuitry which can implement the concept proposed by Westra et al.

### SUMMARY OF INVENTION

In accordance with the invention, parasitic feed-through capacitance effects are reduced in a resonator circuit by separating the resonator signal from feed-through capacitance signal and then detecting the resonator signal with comparator circuitry. A square wave output of the comparator is then feed back to the input of the resonator to form an oscillator circuit.

More particularly, in specific embodiments, the separation of the resonator signal from the feed-through capacitance signal is effected by serial integrator and differentiator circuitry or by trans-impedance amplifier circuitry. The comparator circuitry can include control/delay circuitry for enabling the comparator at a correct time period. The invention can be implemented by using microelectromechanical servers (MEMS) in a strain gauge function.

The invention and object and features thereof will be more readily apparent from the following detailed description and appended claims when taken with the drawings.

### BRIEF DESCRIPTION OF DRAWINGS

FIG. 1 is a schematic of a resonator synchronized relaxation oscillator.

FIG. 2 illustrates voltage waveforms in the circuitry of FIG. 1 as illustrates separation of resonator and feed-through capacitive signals.

FIG. 3 is a schematic of oscillator circuitry in accordance with one embodiment of the invention.

FIG. 4 is a schematic of oscillator circuitry in accordance with another embodiment of the invention.

FIG. 5 is a schematic of integrator and differentiator circuitry in the comparator of FIG. 4.

FIG. 6 illustrates voltage detection in the circuits of FIGS. 3 and 4.

FIG. 7 is a schematic of oscillator circuitry in accordance with another embodiment of the invention.

FIG. 8 illustrates signal separation in the circuit of FIG. 7.

### DETAILED DESCRIPTION

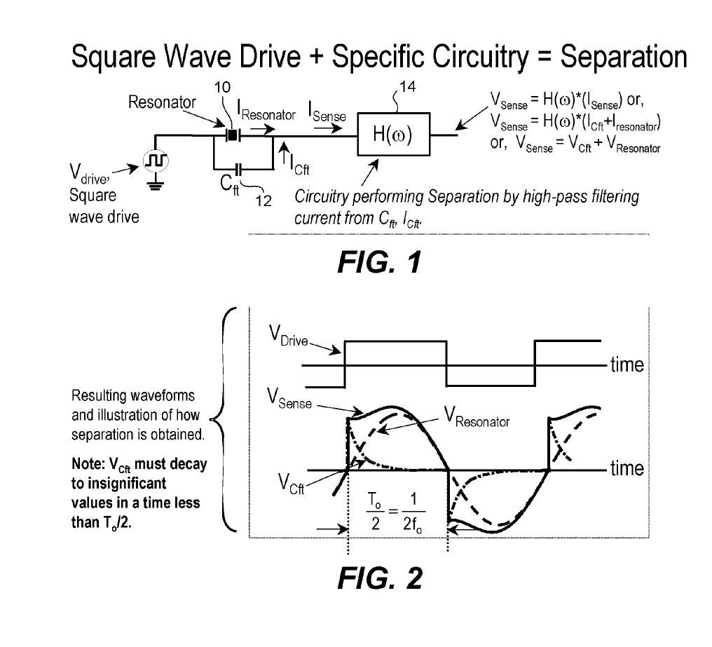

FIG. 1 is a schematic of a resonator oscillator circuit with separation of capacitor feed-through signal from the desired output signal from the resonator such as proposed by Westra et al., supra. The resonator 10 is driven by a square wave drive, and resonator current and current from the parallel feed-through capacitor 12 are passed to a high pass filter 14 having a pass function, H(ω). The sense voltage is then returned to the input of the resonator to form an oscillator.

FIG. 2 illustrates voltage waveforms in the circuit of FIG. 1. The output of the circuit due to the feed-through capacitor must decay quickly in time compared to the output due to the resonator. The high pass filter waits until the output due to the pass-through capacitance is insignificant when compared to the resonator output. At this time, the output due to the resonator can be detected. The voltage from the pass-through capacitance, V_{cft}, must decay to insignificant value in a time less than a half period of the oscillation frequency, or T₀/2=½f₀.

However, the resonator oscillator as proposed by Westra et al. is difficult to realize in actual practice. In accordance with the invention, resonator circuits which can separate the signals are more practical.

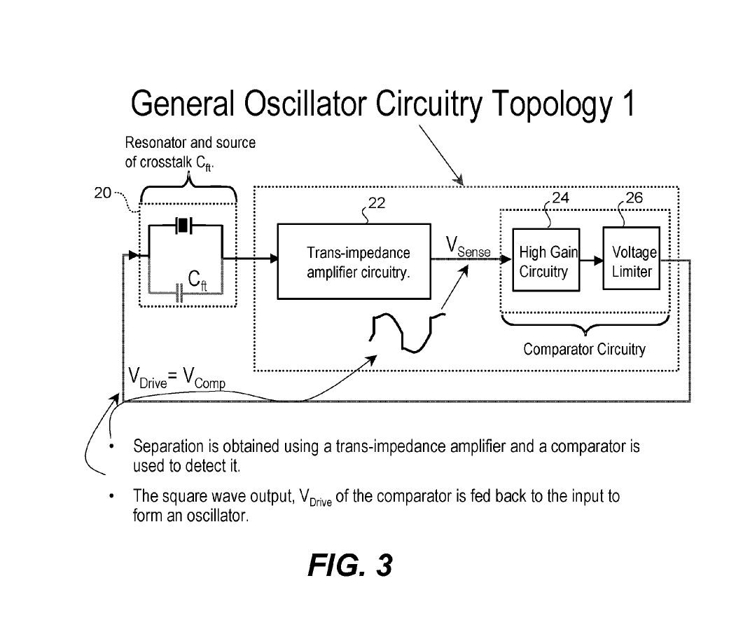

FIG. 3 is a schematic of one embodiment of the invention in which the resonator and source of crosstalk shown generally at 20 provide output signals to a trans-impedance amplifier circuitry 22 for signal separation. The separated resonator voltage, Vₛₑₙₛₑ, from trans-impedance amplifier 22 is then passed to comparator circuitry including high gain circuitry 24 and a voltage limiter 26. The comparator circuitry then provides a square wave output, V_{drive}, which is fed back to the input of the resonator 20 to form an oscillator. Here separation is obtained using the trans-impedance amplifier, and the comparator detects the resonator signal.

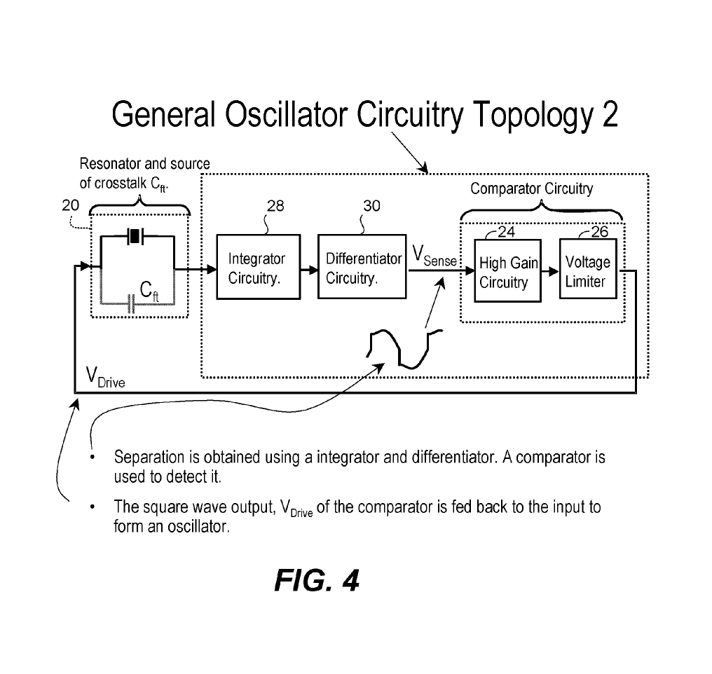

FIG. 4 is a schematic of another embodiment of the invention in which the output of the resonator and feed-through capacitor shown generally at 20 is applied to an integrator circuitry 28 with the integrated output then applied to differentiator circuitry 30. The output of differentiator circuitry 30 is then applied to the comparator circuitry comprising high gain circuitry 24 and voltage limiter 26. Again, the comparator circuitry provides a square wave output, V_{drive}, which is fed back to the input of the resonator to form an oscillator.

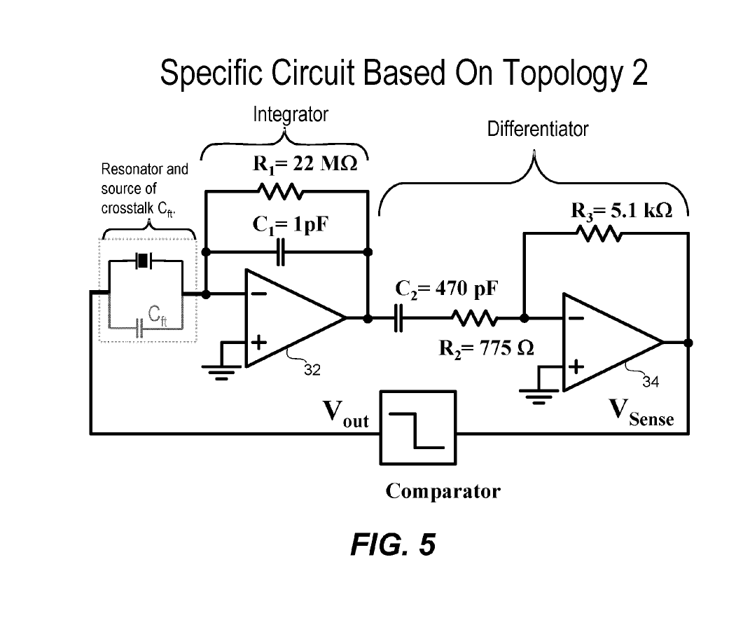

FIG. 5 is a schematic of integrator and differentiator circuitry of the block diagram of FIG. 4. Integrator 28 comprises a differential amplifier 32 with capacitive and resistive feedback, and the output of differential amplifier 32 passes through a resistive capacitive circuit to an input of a second differential amplifier 34 having resistive feedback. Differential amplifier 32, with its associated feedback, functions as the integrator 28, and differential amplifier 34, with its resistive feedback, comprises the differentiator 30. The output of the differentiator is then passed through the comparator circuitry and back to the input of the resonator as described above.

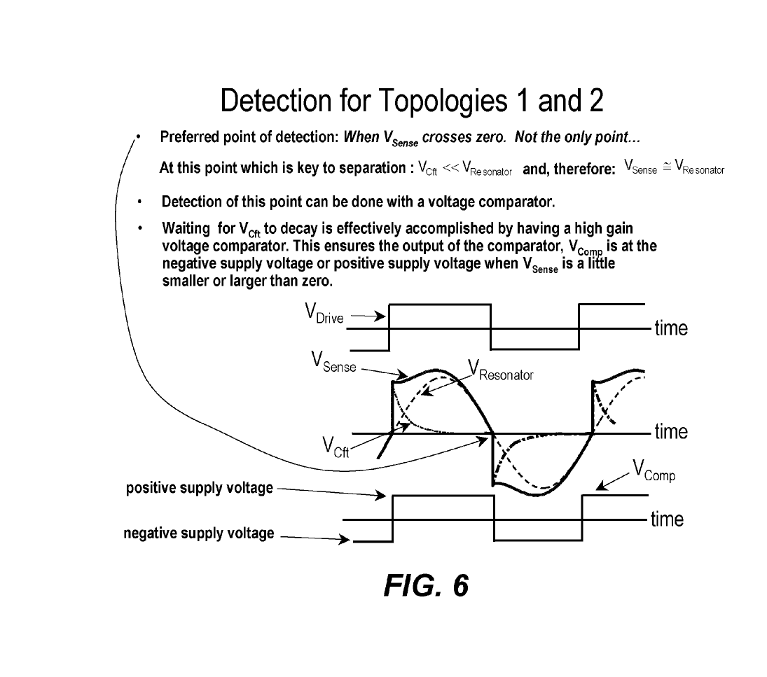

FIG. 6 illustrates signal detection for the circuit of FIGS. 3 and 4. The square wave drive voltage, V_{drive}, is shown at the top and Vresonator and V_{cft}, are shown alone with Vₛₑₙₛₑ. Again, V_{cft} must decay in less than a half time period of the resonator frequency for signal separation. Detection of the resonator voltage at this point can be done by a voltage comparator. Waiting for V_{cft} to decay is effectively accomplished by having a high gain voltage comparator. This ensures the output of the comparator, Vcomp is at the negative supply voltage or positive supply voltage when Vₛₑₙₛₑ is a little smaller or larger than 0.

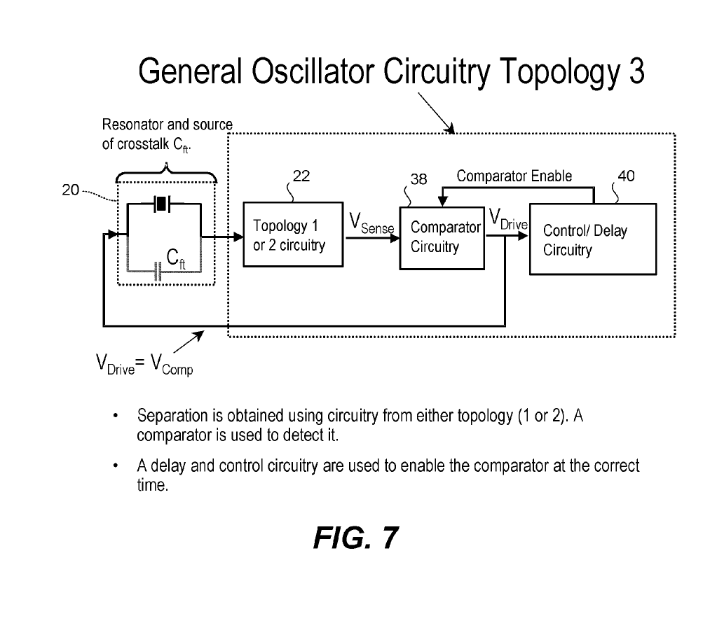

FIG. 7 is a schematic of another embodiment of the invention in which the comparator circuitry 38 is controlled by a control/delay circuitry 40. The output of the resonator and parallel feed-through capacitance is again applied to trans-impedance amplifier circuitry 22 of FIG. 3 or the integrator and differentiator circuitry of FIG. 4. Comparator circuitry 38 receives the voltage and detects the resonator frequency with comparator circuitry 38 being enabled by the control/delay circuitry 40 at the correct time when the feed-through capacitance signal has decayed.

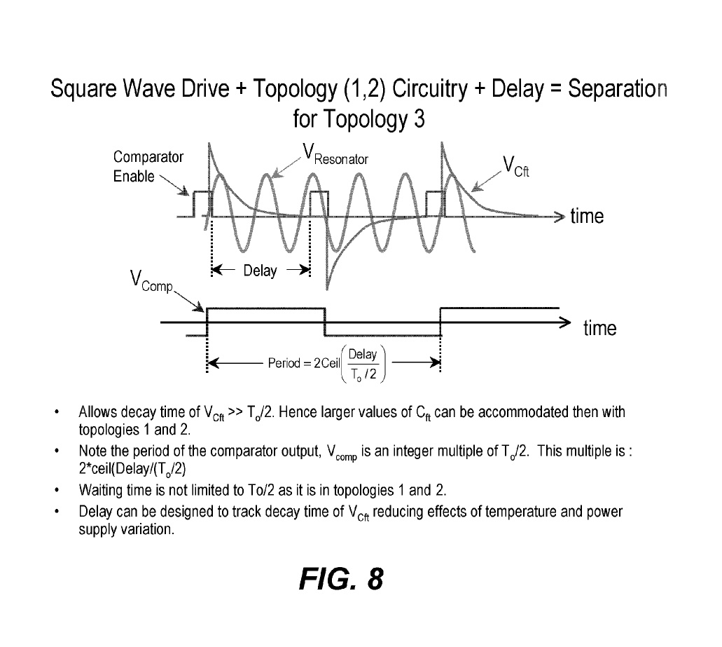

FIG. 8 illustrates the square wave drive with the topology separation circuitry and delay for effecting separation in the circuitry of FIG. 7. Comparator enable signal occurs when the feed-through capacitance signal has decayed and the comparator output, Vcomp, corresponds to the resonator voltage. Use of the comparator enable allows the decay time of V_{cft} to be much greater than T₀/2, hence larger values of C_{ft} can be accommodated when compared with the circuits of FIGS. 3 and 4. Here the period of the comparator output, Vcomp, is an integer multiple of T₀/2. This multiple is 2·cell (Delay/T₀/2). With this embodiment, the waiting time is not limited to T₀/2 as it is in the circuits of FIGS. 3 and 4. Further, the delay can be designed to track decay time of V_{cft}, thereby reducing effects of temperature and power supply variation. The point of detection is at the zero crossing of Vₛₑₙₛₑ when V_{cft} is much smaller than Vresonator. Thus, Vₛₑₙₛₑ will be approximately the value of Vresonator. Waiting for V_{cft} to decay is effectively accomplished by having a high gain voltage comparator detect a valid zero crossing. A delay is then used to disable the comparator until V_{cft} has decayed sufficiently thus allowing the comparator to detect the next valid zero crossing.

While the invention has been described with reference to specific embodiments, the description is illustrative of the invention and is not to be construed as limiting the invention. Various modifications and applications may occur to those skilled in the art without departing from the spirit and scope of the invention as defined by the appended claims.

What is claimed is:

1. A resonator circuit comprising:
a resonator body having an input and an output,
an integrator connected to the resonator output for integrating an output signal at the output,
a differentiator connected to receive an integrated output from the integrator,
a comparator connected to the differentiator for determining when an output voltage from the differentiator reaches a predetermined voltage, and
a feedback loop from the comparator to the resonator input for applying a square wave comparator output voltage to the resonator.

2. The resonator circuit as defined by claim 1 wherein the comparator output applied to the resonator input causes oscillation in the resonator body.

3. The resonator circuit as defined by claim 2 wherein the resonator body functions as a strain sensor and oscillation is at a frequency indicative of strain in the resonator body.

4. The resonator circuit as defined by claim 3 wherein the integrator comprises a first operational amplifier having parallel capacitive and resistive feedback.

5. The resonator circuit as defined by claim 4 wherein the differentiator comprises a second operational amplifier having a resistive feedback and a serial capacitive and resistive connection from the integrator to an input to the differentiator.

6. The resonator circuit as defined by claim 5 and further including control and delay circuitry responsive to the output voltage from the comparator and enabling the comparator during a time period when voltage from parasitic capacitance has decayed to a predetermined level.

7. The resonator circuit as defined by claim 6 wherein the resonator circuit functions as a square wave oscillator.

8. The resonator circuit as defined by claim 7 wherein the square wave oscillator functions as a strain sensor.

9. The resonator circuit as defined by claim 5 wherein the resonator circuit functions as a square wave oscillator.

10. The resonator circuit as defined by claim 9 wherein the square wave oscillator functions as a strain.

11. The resonator circuit as defined by claim 1 wherein the resonator body comprises a microelectromechanical structure (MEMS).

12. A resonator circuit comprising:
a resonator body having an input and an output,
a trans-impedance amplifier operably connected to the resonator output for amplifying an output signal,
comparator circuitry operably connected to receive a sense voltage from the trans-impedance amplifier and provide a square wave output signal, and
a feedback loop for applying the square wave output signal to the input of the resonator body.

13. The resonator circuit of claim 12 wherein the comparator circuitry comprises high gain circuitry for receiving the sense voltage and a voltage limiter operably connected to the high gain circuitry.
